(19) United States
(12) Patent Application Publication
(10) Pub. No.: US 2012/0138344 A1
(43) Pub. Date: Jun. 7, 2012

(54) PRINTED CIRCUIT BOARD

(75) Inventors: YING-TSO LAI, Tu-Cheng (TW); YUNG-CHIEH CHEN, Tu-Cheng (TW); JIA-CHI CHEN, Tu-Cheng (TW)

(73) Assignee: HON HAI PRECISION INDUSTRY CO., LTD., Tu-Cheng (TW)

(21) Appl. No.: 12/965,832

(22) Filed: Dec. 11, 2010

(30) Foreign Application Priority Data
Dec. 3, 2010 (TW) 99142001

(51) Int. Cl. H05K 1/03

(52) U.S. Cl. 174/255

(57) ABSTRACT

A printed circuit board is constructed from various woven fiberglass fabrics, strengthened and bound together with epoxy resin, and includes a signal layer. The signal layer includes a positive differential signal line and a negative differential signal line laid out in parallel following a zig-zag pattern. A first distance and a second distance is designed at a ratio of 1:7. The first distance is a perpendicular distance between a highest point of the negative differential signal line and a reference line formed by connecting all lowest points of the negative differential signal line. The second distance is a perpendicular distance between a lowest point and an adjacent highest point of the negative differential signal line along the direction of the reference line.

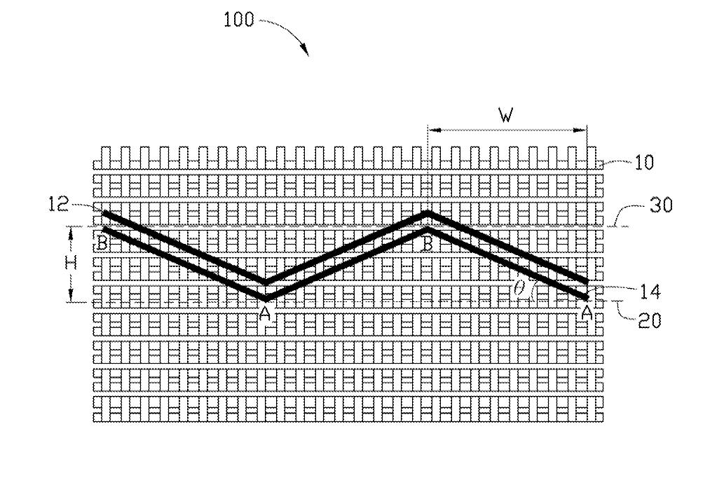

### BACKGROUND

1. Technical Field

The present disclosure relates to a printed circuit board (PCB).

2. Description of Related Art

Many PCBs are constructed from various woven fiberglass fabrics, and strengthened and bound together with epoxy resin. The fiberglass and epoxy resin may have different levels of permittivity, presenting a non-homogeneous medium for signal transmission. The non-homogeneous medium in the PCBs may influence signal transmission, called fiber-weave effect. An ordinary method for reducing fiber-weave effect is to route lines in a zig-zag pattern in the PCBs. However, in common zig-zag routing, an angle of each turning will mainly be greater than 10 degrees, and specifically, 11.3 degrees. Therefore, the common zig-zag routing may occupy a lot of layout space and is not easy to be laid out on a turning point of the signal line.

### BRIEF DESCRIPTION OF THE DRAWING

Many aspects of the present embodiments can be better understood with reference to the following drawing. The components in the drawing are not necessarily drawn to scale, the emphasis instead being placed upon clearly illustrating the principles of the present embodiments.

The drawing is a horizontal cross-sectional, schematic view of an embodiment of a signal layer of a printed circuit board.

### DETAILED DESCRIPTION

The disclosure, including the accompanying drawing, is illustrated by way of example and not by way of limitation. It should be noted that references to “an” or “one” embodiment in this disclosure are not necessarily to the same embodiment, and such references mean at least one.

Referring to the drawing, an embodiment of a printed circuit board (PCB) 100 includes a signal layer 10. The signal layer 10 includes a positive differential signal line 12 and a negative differential signal line 14. The PCB 100 may further include other layers and other signal lines, which fall within well-known technologies, and are therefore not described here.

The PCB 100 is constructed from various woven fiberglass fabrics, then strengthened and bound together with epoxy resin. The positive differential signal line 12 and the negative differential signal line 14 of the PCB 100 are laid out to zig-zag routing in parallel to reduce fiber-weave effect.

There is a first reference line 20 formed by connecting all lowest points A of the negative differential signal line 14 together. There is a second reference line 30 formed by connecting all highest points B of the negative differential signal line 14 together. A perpendicular distance between a highest point B and the first reference line 20 is H. A distance between a lowest point A and an adjacent highest point B along the direction of the first reference line 20 is W (namely a half of the distance between two lowest points A). An angle between a segment of the negative differential signal line 14 and first reference line 20 is θ. In one embodiment, the distance H is substantially 25 mils, the distance W is substantially 175 mils, therefore a ratio between the distance H and the distance W is equal to 25:175=1:7. Therefore, the angle θ is 8.1 degrees.

The PCB 100 can reduce fiber-weave effect. Having the distance H and the distance W at a ratio of 1:7, makes the angle θ be reduced to 8.1 degrees, which can save a lot of space over conventional angles of 10 degrees and more in common zig-zag routing. Therefore, the zig-zag routing design of the PCB 100 does not occupy a lot of layout space, and easy to be laid out on a turning point of the signal lines 12 and 14.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A printed circuit board (PCB) constructed from various woven fiberglass fabrics, strengthened and bound together with epoxy resin, the PCB comprising:
a signal layer comprising a positive differential signal line and a negative differential signal line laid out in parallel following a zig-zag pattern;
wherein a first distance and a second distance is designed at a ratio of 1:7, wherein the first distance is a perpendicular distance between a highest point of the negative differential signal line and a reference line formed by connecting all lowest points of the negative differential signal line, and the second distance is a perpendicular distance between a lowest point and an adjacent highest point of the negative differential signal line along the direction of the reference line.

2. The PCB of claim 1, wherein the first distance is substantially 25 mils, the second distance is substantially 175 mils.
